(19) United States
(12) Patent Application Publication
(10) Pub. No.: US 2025/0029866 A1
(43) Pub. Date: Jan. 23, 2025

(54) WAFER BONDING CHUCK WITH DISCRETE ACTUATORS

(71) Applicant: Micron Technology, Inc., Boise, ID (US)

(72) Inventor: Craig A. Hickman, Boise, ID (US)

(21) Appl. No.: 18/773,044

(22) Filed: Jul. 15, 2024

Related U.S. Application Data
(60) Provisional application No. 63/527,900, filed on Jul. 20, 2023.

(51) Int. Cl. H01L 21/687; H01L 21/683; H01L 23/00

(52) U.S. Cl. CPC H01L 21/6875; H01L 21/6838; H01L 24/74; H01L 24/80; H01L 2224/74; H01L 2224/80895; H01L 2224/80896

(57) ABSTRACT

A semiconductor wafer bonding tool is provided. The semiconductor wafer bonding tool can be used to perform a wafer-wafer bonding between a first semiconductor wafer and a second semiconductor wafer. The semiconductor wafer bonding tool includes a wafer bonding chuck configured to support a first semiconductor wafer at a first side. A plurality of discrete actuators are disposed at the first side of the wafer bonding chuck. Respective actuators of the plurality of discrete actuators are capable of displacing independently of one another. The respective actuators can be displaced based on one or more characteristics of the first semiconductor wafer or the second semiconductor wafer. In doing so, an improved wafer-wafer bonding process can be implemented.

### CROSS-REFERENCE TO RELATED APPLICATION(S)

The present application claims priority to U.S. Provisional Patent Application No. 63/527,900, filed Jul. 20, 2023, the disclosure of which is incorporated herein by reference in its entirety.

### TECHNICAL FIELD

The present disclosure generally relates to wafer bonding tools and more particularly relates to a wafer bonding chuck with discrete actuators.

### BACKGROUND

Wafer bonding is a wafer-level packaging technology that can be used to form semiconductor device assemblies. Wafer bonding is often performed using a bonding chuck capable of contacting two semiconductor wafers in a controlled manner. During wafer bonding, the two semiconductor wafers can be brought into contact with one another at their respective bonding surfaces. The bonding surfaces can include conductive pads coupled with circuitry at each of the respective wafers and dielectric material surrounding the conductive pads. Once contacting, the conductive pads on each of the two semiconductor wafers can bond to form interconnects between the wafers. Similarly, the dielectric material at each respective wafers can bond to mechanically couple the two semiconductor wafers.

### BRIEF DESCRIPTION OF THE DRAWINGS

FIG. 1 illustrates a simplified perspective view of a wafer bonding chuck.

FIG. 2 illustrates a simplified schematic cross-sectional view of a wafer bonding tool during a wafer-wafer bonding process in accordance with an embodiment of the present technology.

FIG. 3 illustrates a simplified schematic cross-sectional view of a wafer bonding tool during a wafer-wafer bonding process in accordance with an embodiment of the present technology.

FIG. 4 illustrates a schematic view of a wafer bonding tool in accordance with an embodiment of the present technology.

FIG. 5 illustrates a method for performing a wafer-wafer bonding process in accordance with an embodiment of the present technology.

### DETAILED DESCRIPTION

Semiconductor devices are integrated in many devices to implement memory cells, processor circuits, imager devices, and other functional features. As more applications for semiconductor devices are discovered, designers are tasked with creating improved devices that can perform a greater number of operations per second, store greater amounts of data, or operate with a higher level of security. To accomplish this task, designers continue to develop new techniques to increase the number of circuit elements on a semiconductor device without simultaneously increasing the size of the device.

One such technique is to implement stacked semiconductor devices with multiple semiconductor dies assembled in a vertical stack. Interconnects can be created between the semiconductor dies to enable signals to be communicated between the dies. In some cases, the stacked semiconductor device can be created through wafer-wafer bonding. For example, a semiconductor wafer can include multiple semiconductor dies. Multiple semiconductor wafers can be bonded to create a vertical stack of wafers such that corresponding dies on the wafers bond to form multiple die stacks. The various die stacks can be singulated from the stack of wafers to create a stack of semiconductor dies.

Some wafer-wafer bonding processes present challenges. For example, wafer-wafer bonding can be performed by placing two semiconductor wafers in close proximity and contacting the wafers at their center (e.g., in a high temperature environment). Once the wafers contact, the wafers can bond to one another. The wafers can bond to one another in accordance with a bond wave, which causes the wafer to displace. As the bond wave propagates from the centers of the wafers to the edges, the bonding surfaces of the wafers can become misaligned. This misalignment can cause a portion of a bonding surface of a first wafer to bond with a non-analogous portion of a bonding surface of a second wafer, which can create voids along a bonding interface between the first and second wafers. The voids can occur when portions of the bonding surfaces of the wafers are not bonded. These voids can decrease the strength of the bond between the wafers or increase the stress in the wafers, which can decrease the mechanical strength of the semiconductor devices. Moreover, the misalignment of the wafers can cause interconnects between the wafers to become misaligned, which can cause the semiconductor devices fabricated from the wafers to become inoperable or perform unreliably.

To solve these problems and others, the present technology relates to a wafer bonding tool that includes a wafer bonding chuck with a plurality of discrete actuators. The semiconductor wafer bonding tool can be used to perform a wafer-wafer bonding between a first semiconductor wafer and a second semiconductor wafer. The plurality of discrete actuators are disposed at the first side of the wafer bonding chuck. Respective actuators of the plurality of discrete actuators are capable of displacing independently of one another. The first semiconductor wafer can be attached to the wafer bonding chuck at the first side (e.g., through suction) such that when the actuators displace, the first semiconductor wafer displaces with the respective actuators.

The respective actuators can displace based on one or more characteristics of the first semiconductor wafer or the second semiconductor wafer. For example, the respective actuators can displace based on the propagation of a bonding wave across the first semiconductor wafer or the second semiconductor wafer. The one or more characteristics of the first semiconductor wafer can be determined through measurement or simulation. For example, the behavior of the first and second wafer during the wafer-wafer bonding process can be predicted based on the properties of the wafers (e.g., size, thickness, material, shape, impurities) and the bonding process (e.g., bonding temperature, force applied, separation between the wafers). In this way, the displacement of the wafers during the bonding process (e.g., as a result of the bonding wave) can be determined. In other cases, the one or more characteristics of the wafers can be determine based on actual measurements of bonding processes. For example, an optical sensor (e.g., lidar sensor, radar sensor, image sensor) can be used to determine the displacement of the wafers during the bonding process. In some embodiments, stress sensors can be used to determine the displacement of the wafers. In aspects, the measurements can be performed in real time. That is, the measurements can be determined during the bonding process, and the actuators can be displaced based on the measurements during the same bonding process. In other cases, the actuators can be displaced based on measurements taken during a previous bonding process.

In general, the respective actuators can displace to maintain alignment between the first and second semiconductor wafers. For example, the displacement of the actuators can cause corresponding portions of the bonding surfaces on the first and second wafers to be parallel with one another to ensure a uniform bond between the wafers. In some cases, the displacement of the actuators can compensate for displacement of the first wafer during the bonding process (e.g., due to the propagation of the bond wave). In yet other aspects, the actuators can be used to bring portions of the bonding surfaces of the wafers into contact with one another to provide greater control over the bonding process.

In contrast to other techniques, the present technology enables localized control of the wafer-wafer bonding process. For example, the discrete actuators can displace relative to one another to enable individual portions of the first semiconductor wafer to be adjusted with minimal impact to other portions of the first semiconductor wafer. As a result, wafer-wafer bonding can be controlled to a finer granularity, which can improve the bond quality between two wafers.

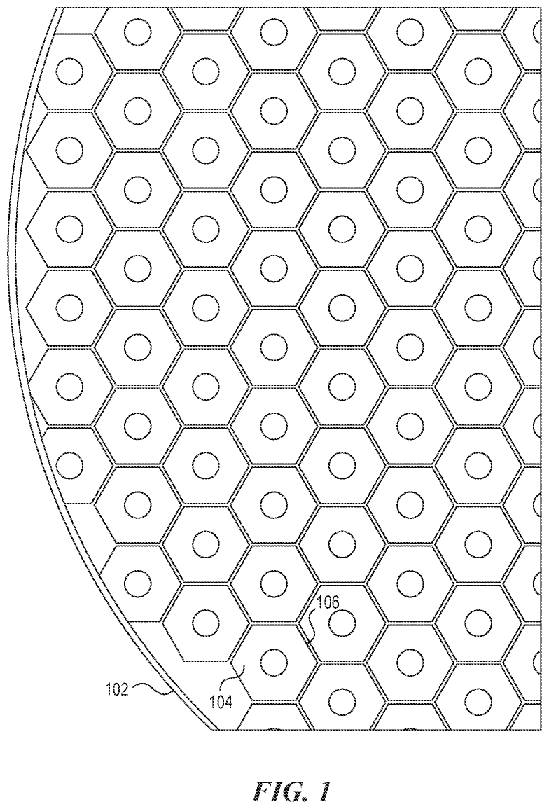

FIG. 1 illustrates a wafer bonding chuck 102 that includes multiple discrete actuators 104. As illustrated, the wafer bonding chuck 102 can have a support surface (e.g., the illustrated surface) at which a semiconductor wafer can be attached. The wafer bonding chuck 102 can have any number of shapes. For example, as illustrated, the wafer bonding chuck 102 is circular; however, in other embodiments, the wafer bonding chuck 102 is rectangular, triangular, polygonal, or any other shape. The discrete actuators 104 can be disposed about the wafer bonding chuck 102. For example, the discrete actuators 104 can be arranged in a grid that spans at least a portion of the support surface of the wafer bonding chuck 102. The density of the discrete actuators 104 can vary across embodiments. For example, in some cases, the discrete actuators 104 are arranged such that the discrete actuators 104 cover over 90, 95, or 99 percent of the support surface of the wafer bonding chuck 102. In other cases, the discrete actuators 104 cover a smaller portion of the support surface of the wafer bonding chuck (e.g., less than 25, 50, 75, or 80 percent). In this way, the discrete actuators 104 can be arranged tightly with one another or scattered sparsely across the wafer bonding chuck 102. For example, the discrete actuators 104 can be placed at locations on the support surface that correspond to portions of a semiconductor wafer at which large displacement is experienced during bonding.

The discrete actuators 104 can be disposed such that gaps 106 are present between the various actuators. Based on the density and the arrangement of the discrete actuators 104, the gaps 106 can vary in size. In aspects, the wafer bonding chuck 102 can include a vacuum (not shown) that is capable of providing suction through the gaps 106. In this way, portions of the semiconductor wafer can remain attached to the wafer bonding chuck 102 even when one or more of the discrete actuators 104 are displaced. In some embodiments, gaps 106 can be placed within the discrete actuators 104 (e.g., at the centers of the discrete actuators 104) to enable suction to pass through the gaps 106. In other embodiments, the semiconductor wafer can be attached to the wafer bonding chuck 102 through an adhesive or clamp.

The discrete actuators 104 can have various shapes. As illustrated, the discrete actuators 104 are polygonal (e.g., triangular, rectangular, pentagonal, hexagonal, heptagonal, octagonal), which can enable the discrete actuators 104 to be arranged densely. In other cases, the discrete actuators 104 are elliptical or any other shape. The discrete actuators 104 can include protruded portions on an exposed surface. The protruded portions can be configured to support the semiconductor wafer, for example, so that the semiconductor wafer contacts only the protruded portions when attached to the wafer bonding chuck 102. As illustrated, the protruded portions are located at the center of the discrete actuators 104; however, in other cases, the protruded portions can be located at other locations (e.g., the edges) of the discrete actuators 104. In yet other aspects, the discrete actuators 104 need not include a protruded portion. Instead, the discrete actuators 104 can have a flat exposed surface at which the semiconductor wafer is attached.

Although illustrated as separate structures, the discrete actuators 104 can be disposed under a continuous surface. For example, although the discrete actuators 104 can displace independently of one another, each discrete actuator need not be disposed under a discrete structure. Instead, the discrete actuators 104 can be placed under a continuous surface such that the discrete actuators 104 displace to cause displacement at different portions of the continuous surface. In this way, the exposed surface of the discrete actuators need not have the gaps 106.

Each of the discrete actuators 104 can be displaced independently. For example, the different discrete actuators 104 can be displaced in different directions or by different amounts. Each of the discrete actuators 104 can comprise a motor or other actuator capable of converting potential energy (e.g., electrical energy) into mechanical energy. In some cases, the discrete actuators 104 can comprise a piezoelectric motor. Given that the displacement of the wafers caused by the bonding process can be relatively small, the discrete actuators 104 can displace by a relatively small amount (e.g., less than 10 microns, less than 1 micron, less than 0.1 microns). In this way, the discrete actuators 104 can comprise motors that are capable of causing small displacements.

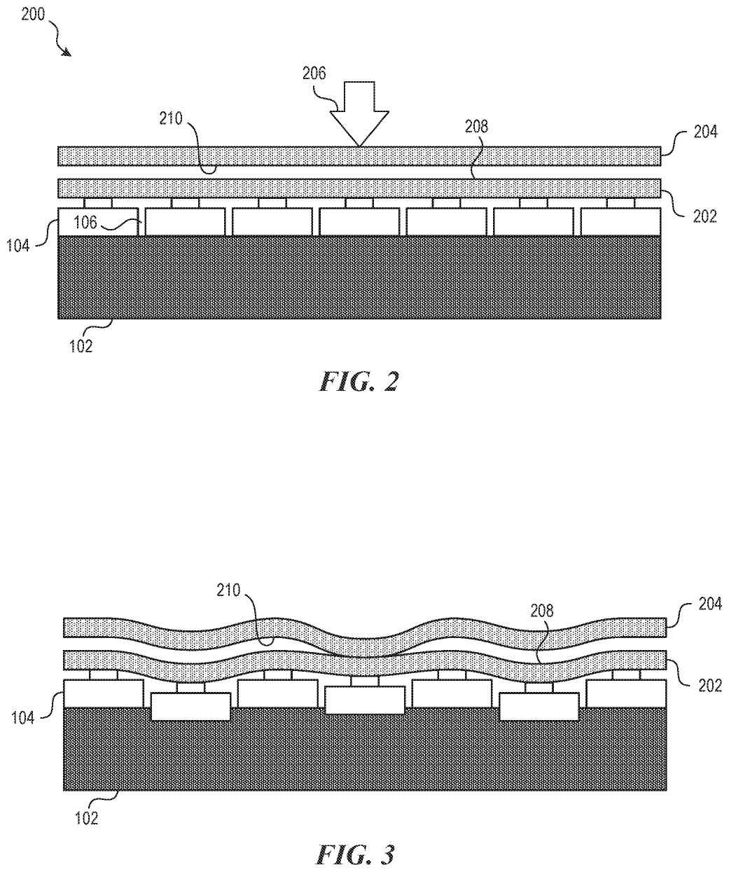

FIG. 2 illustrates a simplified schematic cross-sectional view of a wafer bonding tool 200 during a wafer-wafer bonding process in accordance with an embodiment of the present technology. The wafer bonding tool 200 includes a wafer bond chuck 102, which includes multiple discrete actuators 104. A first semiconductor wafer 202 can be attached to the wafer bonding chuck 102 such that the first semiconductor wafer 202 contacts the discrete actuators 104. The first semiconductor wafer 202 can attach to the wafer bonding chuck 102 through suction, adhesive, clamps, or any other technique. In some embodiments, the first semiconductor wafer 202 attaches to wafer bonding chuck through suction that passes through the gaps 106.

A second semiconductor wafer 204 is similarly disposed adjacent to and spaced from the semiconductor wafer 202. In some embodiments, a spacer (not shown) is disposed between the first semiconductor wafer 202 and the second semiconductor wafer 204 to maintain separation between the wafers. The second semiconductor wafer 204 can attach to the wafer bonding tool 200 through any number of techniques. For example, the second semiconductor wafer 204 can be clamped to a lower portion of the bonding tool (e.g., at the wafer bond chuck 102). In other cases, the wafer bonding tool can include an upper wafer bond chuck (not shown) to which the second semiconductor wafer 204 attaches (e.g., through suction, adhesion, clamping, or any other technique). In some embodiments, the upper wafer bond chuck can include discrete actuators to support and adjust the configuration of the second semiconductor wafer 204. In this case, the discrete actuators at the upper bond chuck can perform similar functions to the discrete actuators 104 at wafer bond chuck 102.

Turning back to FIG. 2, the wafer bonding tool 200 is illustrated at the beginning of a wafer-wafer bonding process before bonding has begun. Before bonding has begun, the discrete actuators 104 can be configured in a rest position, where the discrete actuators 104 form a level upper surface at which the first semiconductor wafer 202 can be disposed. Given that the first semiconductor wafer 202 can attach to the wafer bond chuck 102, the first semiconductor wafer 202 can be flat at the beginning of the wafer bonding process (e.g., absent of deformation caused by wafer stresses). The second semiconductor wafer 204 can be similarly flattened against an upper wafer bond chuck (not shown). In some embodiments, the discrete actuators 104 or discrete actuators on the upper wafer bond chuck can be displaced to flatten the first semiconductor wafer 202 or the second semiconductor wafer 204 on the wafer bond chuck 102 or the upper wafer bond chuck, respectively. The second semiconductor wafer 204 is aligned with the first semiconductor wafer 202 (e.g., so that the edges of the wafers or corresponding semiconductor dies on the wafers are at the same lateral position). In aspects, the wafers can be aligned using optical sensors. When the wafers are aligned, a bonding surface 208 of the first semiconductor wafer 202 can face toward a bonding surface 210 of the second semiconductor wafer 204.

Once aligned, bonding can be initiated by applying a force 206 to the first semiconductor wafer 202 or the second semiconductor wafer 204 to bring a portion of the first semiconductor wafer 202 and a portion of the second semiconductor wafer 204 in contact with one another (e.g., at bonding surface 208 and bonding surface 210). As illustrated, the force 206 can be applied at a center of the first semiconductor wafer 202 or the second semiconductor wafer 204 to begin the bonding process at the center of the wafers. The force 206 can be applied by a probe or chuck that can press down on the first semiconductor wafer 202 or the second semiconductor wafer 204. In other cases, the force 206 can be applied by releasing suction attaching a portion of the first semiconductor wafer 202 or a portion of the second semiconductor wafer 204 (e.g., to enable the wafer to return to a warped shape in which the semiconductor wafers contact). In yet other aspects, the force 206 can be applied using the discrete actuators. For example, one or more of the discrete actuators 104 (e.g., at the center of the wafers) can be displaced to cause a portion of the first semiconductor wafer 202 to contact a portion of the second semiconductor wafer 204. When the first semiconductor wafer 202 and the second semiconductor wafer 204 contact, the bonding surface 208 and the bonding surface 210 can bond to one another.

The application of force 206 to the first semiconductor wafer or the second semiconductor wafer can be caused by directly or indirectly applying a force to at least one wafer. For example, the force 206 can be applied by a physical object that contacts at least one wafer or by air that pushes or pulls at least one wafer. In some embodiments, the force 206 can be a magnetic force that attracts or repels the wafer. In yet another aspect, the force 206 can be caused by stress in the wafer. For example, the force 206 can be caused by releasing a portion of the wafer from the chuck to which it is attached (e.g., stopping suction at a portion of the wafer) while leaving another portion of the wafer attached to the chucks (e.g., maintaining suction at this portion). In this way, the stress in the wafers can cause the wafers to deform and contact. In some embodiments, the bonding process is controlled by releasing suction from portions of the wafer at different times during the bonding process (e.g., beginning at the center of the wafer and moving toward the edge of the wafers).

The bonding process can be performed in a heated environment, for example, within an oven. In some cases, the bonding process can be used to form an initial bond between the first semiconductor wafer 202 and the second semiconductor wafer 204, which is later cured at a higher temperature. In other cases, only a single bond is performed. In general, the force 206 applied to the first semiconductor wafer 202 or the second semiconductor wafer 204 can cause a bond to be formed between the wafers, as illustrated in FIG. 3.

FIG. 3 illustrates a simplified schematic cross-sectional view of the wafer bonding tool 200 during a wafer-wafer bonding process in accordance with an embodiment of the present technology. In contrast to FIG. 2, the first semiconductor wafer 202 and the second semiconductor wafer 204 are bonded at their centers (e.g., due to the force 206 applied as illustrated in FIG. 2). A bond wave resulting from the bonding process can propagate through the first semiconductor wafer 202 or the second semiconductor wafer 204 to displace the wafers. As illustrated, the bond wave causes the first semiconductor wafer 202 to displace upward or downward at different locations.

The discrete actuators 104 of the wafer bonding tool 200 can be displaced to maintain alignment between the first semiconductor wafer 202 and the second semiconductor wafer 204 during the wafer bonding process. Given that the second semiconductor wafer 204 is supported by the discrete actuators 104, the second semiconductor wafer 204 can be displaced in response to the displacement of the discrete actuators 104. For example, the discrete actuators 104 can displace to cause a portion of the bonding surface 210 of the second semiconductor wafer 204 to remain parallel with a corresponding portion of the bonding surface 208 of the first semiconductor wafer 202 (e.g., tangent lines at the portion of the bonding surfaces are parallel). The discrete actuators 104 can be displaced based on one or more characteristics of the first semiconductor wafer 202 or the second semiconductor wafer 204. For example, the discrete actuators 104 can be displaced based on the displacement or stress experienced by the first semiconductor wafer 202 or the second semiconductor wafer 204 (e.g., as a result of the bond wave).

In some cases, the discrete actuators 104 can compensate for the propagation of the bond wave through the first semiconductor wafer 202 or the second semiconductor wafer 204. For example, when the bond wave causes the first semiconductor wafer 202 to be displaced upward, one or more of the discrete actuators 104 supporting a corresponding portion of the second semiconductor wafer 202 can be displaced to cause the second semiconductor wafer 204 to displace upward (e.g., by a same amount as the portion of the first semiconductor wafer 202). Alternatively or additionally, when the bond wave would otherwise cause a portion of the second semiconductor wafer 204 to be displaced (e.g., upward), one or more of the discrete actuators 104 that support the portion of the second semiconductor wafer 204 can be displaced in an opposite direction (e.g., downward) to cause the portion of the second semiconductor wafer 204 to remain flat. In other cases, the discrete actuators 104 can be displaced in accordance with other characteristics of the first semiconductor wafer 202 or the second semiconductor wafer 204 not related to the propagation of the bonding wave.

The one or more characteristics of the first semiconductor wafer 202 or the second semiconductor wafer 204 can be measured in any number of ways. For example, displacement of the first semiconductor wafer 202 or the second semiconductor wafer 204 can be measured using an optical sensor or by converting stress measurements from a stress sensor. The one or more characteristics of the first semiconductor wafer 202 or the second semiconductor wafer 204 can be actual measurements taken during the same bonding process in which they are used to displace the discrete actuators 104, a previous bonding process between different wafers (e.g., having similar properties), or measurements from a simulation of a bonding between two wafers (e.g., having similar properties).

The discrete actuators 104 can be displaced independently of one another. For example, a first discrete actuator and a second discrete actuator can be displaced by different amounts at the same time (e.g., without tilting or changing the plane of the discrete actuators 104 within the wafer chuck 102). For example, the first discrete actuator can displace by a first amount (e.g., corresponding to a displacement of the first semiconductor wafer 202 or the second semiconductor wafer 204 at a portion having a same lateral position as the first discrete actuator), and the second discrete actuator can displace by a second amount (e.g., corresponding to a displacement of the first semiconductor wafer 202 or the second semiconductor wafer 204 at a portion having a same lateral position as the second discrete actuator). In contrast to other apparatuses, the wafer bonding tool 200 is capable of localized displacement through the discrete actuators 104, which can improve the alignment between the first semiconductor wafer 202 and the second semiconductor wafer 204 during bonding.

The discrete actuators 104 can be displaced individually. In some cases, the discrete actuators 104 can be displaced as the bond wave propagates. The bond wave can propagate from the center of the wafer to the edge. As the bond wave propagates, additional portions of the first semiconductor wafer 202 and the second semiconductor wafer 204 can contact at the bonding surface 208 and the bonding surface 210. In doing so, the bond between the wafers can be formed. In some cases, only the discrete actuators 104 at a front of the bond wave are actuated. For example, when bonding is first started discrete actuators 104 supporting the center of the second semiconductor wafer 204 can be actuated. As the bond wave propagates outward toward the edge, discrete actuators 104 at the edge of the wafers are displaced (e.g., discrete actuators 104 that correspond to portions of the wafers that have already been bonded or portions that have not yet been bonded are maintained in a neutral position). In this way, only some of the discrete actuators 104 need be displaced at the same time. Alternatively or additionally, the discrete actuators 104 away from the bond wave can be displaced to keep the first semiconductor wafer 202 and the second semiconductor wafer 204 aligned.

Although in the foregoing example embodiments wafer bonding tools have been illustrated and described in a particular configuration, in other embodiments, wafer bonding tools can be provided with different configurations. For example, the wafer bonding tools illustrated in any of the foregoing examples could be implemented with, for example, more or less discrete actuators, a top chuck that includes the discrete actuators, a bottom chuck that includes the discrete actuators, a top and a bottom chuck that includes the discrete actuators, mutatis mutandis.

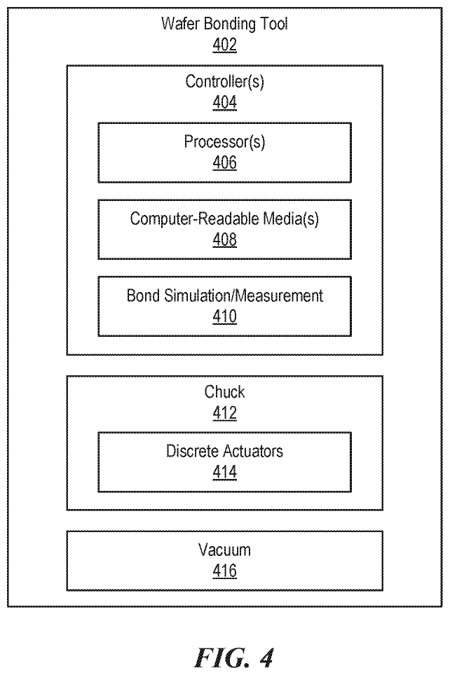

FIG. 4 illustrates a schematic view of a wafer bonding tool 402 (e.g., an example of which is wafer bonding tool 200 illustrated in FIG. 2) in accordance with an embodiment of the present technology. The wafer bonding tool 402 includes a controller 404, including at least one processor 406, at least one computer-readable media 408, and a bond simulation/measurement module 410. The wafer bonding tool 402 includes a wafer bonding chuck 412 (e.g., an example of which is wafer bonding chuck 102 illustrated in FIG. 1) having discrete actuators 414 (e.g., an example of which is discrete actuators 104 illustrated in FIG. 1). The controller 404 can control one or more operations during the wafer bonding process. For example, the controller 404 can displace one or more of the discrete actuators 414 during the wafer bonding process based on one or more characteristics of the wafers. The computer-readable media 408 can include computer-readable instructions that, when executed by the processor 406, perform one or more aspects described herein.

The one or more characteristics of the wafers can be determined using the bond simulation/measurement module 410. The bond simulation/measurement module 410 can include computer-readable media storing instructions that, when executed by at least one processor (e.g., processor 406), cause the controller 404 to receive the one or more characteristics of the wafers. The bond simulation/measurement module 410 can perform or analyze simulations of wafer bonding processes to determine the one or more characteristics of the wafers (e.g., displacement or stress). In some cases, the bond simulation/measurement module 410 can measure current or previous bonding processes to determine the one or more characteristics of the wafers. In some cases, the measurements or simulations are performed by components external to the wafer bonding tool 402 and provided to the bond simulation/measurement module 410 (e.g., where they are analyzed).

The controller 404 can control operations performed using the wafer bonding chuck 412. The wafer bonding chuck 412 can be an upper chuck or a lower chuck. The wafer bonding tool 402 can include the discrete actuators 414 on the upper chuck or the lower chuck. The discrete actuators 414 can be independently displaced to enable localized control of the wafer bonding process.

The wafer bonding tool 402 can further include a vacuum 416 which can be used to attach a semiconductor wafer to the wafer bonding chuck 412 through suction at the wafer bonding chuck 412. In aspects, the controller 404 can control operation of the vacuum 416. For example, the controller 404 can cause the vacuum 416 to provide suction at one or more portions of the wafer bonding chuck 412. In some cases, the controller 404 can cause the vacuum 416 to provide suction at certain portions of the wafer bonding chuck 412 to help facilitate the wafer bonding process. For example, the controller 404 can cause the vacuum 416 to release suction at the center of the wafer bonding chuck 412 but not at the edge of the wafer bonding chuck 412 to initiate the wafer bonding process.

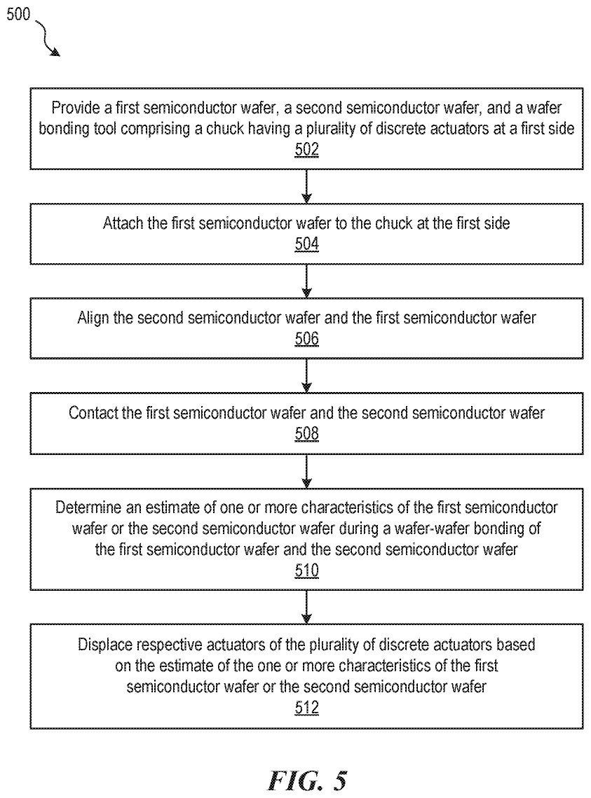

In general, the wafer bonding tool 402 can be used to perform an improved wafer bonding process that provides various advantages over other processes, including enabling better alignment between bonded wafers. FIG. 5 illustrates an example method 500 for performing a wafer-wafer bonding process in accordance with an embodiment of the present technology. Although illustrated in a particular configuration, one or more operations of the method 500 may be omitted, repeated, or reorganized. Additionally, the method 500 may include other operations not illustrated in FIG. 5, for example, operations detailed in one or more other methods described herein. In aspects, the one or more operations of the method 500 can be performed by a wafer bonding tool (e.g., wafer bonding tool 402 of FIG. 4). In some cases, one or more operations of the method 500 can be performed through control by an electronic device (e.g., the controller 404 of FIG. 4).

At 502, a first semiconductor wafer, a second semiconductor wafer, and a wafer bonding tool are provided. The wafer bonding tool has a chuck with a plurality of discrete actuators at a first side. At 504, the first semiconductor wafer is attached to the chuck at the first side. The first semiconductor wafer can be attached to the chuck such that the discrete actuators support the first semiconductor wafer. The semiconductor wafer can be attached to the chuck through suction, through clamps, through adhesive, or through any other technique.

At 506, the second semiconductor wafer is aligned with the first semiconductor wafer while maintaining distance between the wafers. For example, the first semiconductor wafer and the second semiconductor wafer can be separated by a spacer. The second semiconductor wafer can be attached (e.g., clamped) to a portion of the wafer bonding tool (e.g., at the wafer bond chuck). In some embodiments, the second semiconductor wafer can be attached to an additional wafer bonding chuck. The first semiconductor wafer and the second semiconductor wafer can be optically aligned. Once aligned, the wafers can be bonded.

At 508, the first semiconductor wafer and the second semiconductor wafer are contacted. The wafers can be contacted by applying a force to the first semiconductor wafer or the second semiconductor wafer. The force can be applied by physically contacting one or more of the wafers with an object. Alternatively or additionally, the force can be applied by applying or releasing suction from a portion of one or more of the wafers, through a magnet, or through any other technique. In aspects, the wafers contact at their center, and the bonding process is initiated from the center.

At 510, an estimate of one or more characteristics of the first semiconductor wafer or the second semiconductor wafer during a wafer-wafer bonding process is determined. In some cases, the estimate of the one or more characteristics can be determined from a simulation or a previous recording of wafers having similar characteristics to the first and second semiconductor wafers. In other cases, the estimate of the one or more characteristics can be determined during the wafer-wafer bonding process between the first semiconductor wafer and the second semiconductor wafer. In aspects, the one or more characteristics can relate to a displacement, stress, or other characteristic of one or more of the wafers.

At 512, respective actuators of the plurality of discrete actuators are displaced during the wafer-wafer bonding process between the first and second semiconductor wafers. The respective actuators can be displaced based on the estimate of the one or more characteristics of the first or second semiconductor wafer during the wafer-wafer bonding process. The respective actuators can be displaced to maintain alignment between the first semiconductor wafer and the second semiconductor during the wafer-wafer bonding process. In general, the method 500 can be performed to assemble a semiconductor device with greater alignment and higher yield, among other advantages.

The semiconductor devices assemblies constructed by practicing one or more aspects of the present disclosure can include memory dies, such as dynamic random access memory (DRAM) dies, NOT-AND (NAND) memory dies, NOT-OR (NOR) memory dies, magnetic random access memory (MRAM) dies, phase change memory (PCM) dies, ferroelectric random access memory (FeRAM) dies, static random access memory (SRAM) dies, or the like. In an embodiment in which multiple dies are provided in a single assembly, the semiconductor devices could include memory dies of a same kind (e.g., both NAND, both DRAM, etc.) or memory dies of different kinds (e.g., one DRAM and one NAND, etc.). In accordance with another aspect of the present disclosure, the semiconductor dies of the assemblies described above could be logic dies (e.g., controller dies, processor dies, etc.), or a mix of logic and memory dies (e.g., a memory controller die and a memory die controlled thereby).

Any one of the semiconductor devices and semiconductor device assemblies constructed in accordance with one or more aspects of the present disclosure can be incorporated into any of a myriad of larger and/or more complex systems. The system can perform any of a wide variety of functions, such as memory storage, data processing, and/or other suitable functions. Accordingly, representative systems can include, without limitation, hand-held devices (e.g., mobile phones, tablets, digital readers, and digital audio players), computers, vehicles, appliances and other products.

Unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization (CMP), or other suitable techniques.

The technology disclosed herein relates to semiconductor devices, systems with semiconductor devices, and related methods for manufacturing semiconductor devices. The term “semiconductor device” generally refers to a solid-state device that includes one or more semiconductor materials. Examples of semiconductor devices include logic devices, memory devices, and diodes, among others. Furthermore, the term “semiconductor device” can refer to a finished device or to an assembly or other structure at various stages of processing before becoming a finished device. Depending upon the context in which it is used, the term “substrate” can refer to a structure that supports electronic components (e.g., a die), such as a printed circuit board (PCB) or wafer-level substrate, a die-level substrate, or another die for die-stacking or 3DI applications.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In some cases, the substrate is a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor wafer bonding tool, comprising:
a chuck configured to support a first semiconductor wafer at a first side, the chuck comprising:
the first side; and
a plurality of discrete actuators at the first side, the plurality of discrete actuators capable of displacing independently of one another.

2. The semiconductor wafer bonding tool of claim 1, further comprising a vacuum configured to provide suction at the first side.

3. The semiconductor wafer bonding tool of claim 2, wherein the plurality of discrete actuators are separated by gaps through which the suction is provided.

4. The semiconductor wafer bonding tool of claim 1, wherein the plurality of discrete actuators are capable of displacing along an axis normal to a plane defined by the first side.

5. The semiconductor wafer bonding tool of claim 1, wherein the plurality of discrete actuators are arranged in an array across the first side.

6. The semiconductor wafer bonding tool of claim 1, wherein the one or more of the plurality of discrete actuators are polygonal.

7. The semiconductor wafer bonding tool of claim 6, wherein the one or more of the plurality of discrete actuators are hexagonal.

8. The semiconductor wafer bonding tool of claim 1, wherein each respective actuator of the plurality of discrete actuators comprise a respective piezoelectric motor configured to displace that respective actuator.

9. The semiconductor wafer bonding tool of claim 1, wherein the plurality of discrete actuators are configured to displace to keep at least a portion of a first bonding surface of the first semiconductor wafer parallel with a corresponding portion of a second bonding surface of a second semiconductor wafer with which the first semiconductor wafer is bonded.

10. The semiconductor wafer bonding tool of claim 9, wherein a respective actuator of the plurality of discrete actuators is configured to displace to different locations at different times during a bonding process between the first semiconductor wafer and the second semiconductor wafer.

11. A method for performing wafer-wafer bonding, comprising:
providing a first semiconductor wafer, a second semiconductor wafer, and a wafer bonding tool comprising a chuck having a plurality of discrete actuators at a first side;
attaching the first semiconductor wafer to the chuck at the first side;
aligning the second semiconductor wafer and the first semiconductor wafer;
contacting the first semiconductor wafer and the second semiconductor wafer;
determining an estimate of one or more characteristics of the first semiconductor wafer or the second semiconductor wafer during a wafer-wafer bonding of the first semiconductor wafer and the second semiconductor wafer; and
responsive to contacting the first semiconductor wafer and the second semiconductor wafer, displacing respective actuators of the plurality of discrete actuators based on the estimate of the one or more characteristics of the first semiconductor wafer or the second semiconductor wafer.

12. The method of claim 11, wherein determining the estimate of the one or more characteristics of the first semiconductor wafer or the second semiconductor wafer is based on a simulated wafer-wafer bond.

13. The method of claim 11, wherein determining the estimate of the one or more characteristics of the first semiconductor wafer or the second semiconductor wafer comprises measuring the one or more characteristics of the first semiconductor wafer or the second semiconductor wafer during the wafer-wafer bonding.

14. The method of claim 11, wherein attaching the first semiconductor wafer to the chuck comprises providing suction at the first side.

15. The method of claim 11, further comprising:
displacing a first actuator of the plurality of discrete actuators to a first location at a first time during the wafer-wafer bonding; and
displacing the first actuator to a second location different from the first location at a second time during the wafer-wafer bonding.

16. The method of claim 11, wherein displacing the respective actuators comprises displacing the respective actuators along an axis normal to a plane defined by the first side.

17. A semiconductor wafer bonding tool, comprising:
a chuck configured to support a first semiconductor wafer at a first side, the chuck comprising:
the first side; and
a plurality of discrete actuators at the first side; and
a controller configured to:
receive an estimate of one or more characteristics of the first semiconductor wafer or a second semiconductor wafer during a wafer-wafer bonding of the first semiconductor wafer and the second semiconductor wafer; and
cause the plurality of discrete actuators to independently displace during the wafer-wafer bonding based on the estimate of the one or more characteristics of the first semiconductor wafer or the second semiconductor wafer.

18. The semiconductor wafer bonding tool of claim 17, wherein:
respective actuators of the plurality of discrete actuators comprise respective piezoelectric motors; and
the controller is configured to actuate the piezoelectric motors based on the estimate of the one or more characteristics of the first semiconductor wafer or the second semiconductor wafer.

19. The semiconductor wafer bonding tool of claim 17, wherein the controller is configured to independently displace the plurality of discrete actuators along an axis normal to a plane defined by the first side.

20. The semiconductor wafer bonding tool of claim 17, wherein the plurality of discrete actuators are arranged in an array across the first side.
